(19) United States
(12) Patent Application Publication
(10) Pub. No.: US 2018/0166294 A1
(43) Pub. Date: Jun. 14, 2018

(54) APPARATUS AND METHODS TO ACHIEVE UNIFORM PACKAGE THICKNESS

(71) Applicant: Intel Corporation, Santa Clara, CA (US)

(72) Inventors: Zheng Zhou, Chandler, AZ (US); Yi Li, Chandler, AZ (US); Tao Wu, Tempe, AZ (US); Nikhil Sharma, San Jose, CA (US)

(21) Appl. No.: 15/377,635

(22) Filed: Dec. 13, 2016

(51) Int. Cl. H01L 21/3105; H01L 21/683; H01L 21/56; H05B 3/22

(52) U.S. Cl. CPC H01L 21/31053; H01L 21/6838; H01L 2021/607; H05B 3/22; H01L 21/56

(57) ABSTRACT

Embodiments herein relate to methods and apparatus to achieve substantially uniform package thickness after forming a buildup layer on a package substrate of an integrated circuit. Some embodiments include applying a resin to the buildup layer to form a resin layer on top of at least a portion of the buildup layer and substantially evening out the surface formed by the resin layer. Some embodiments include vibrating a hot press onto the top surface of the buildup layer and vibrating the hot press in an ultrasonic and/or a scrubbing motion. Other embodiments may be described and/or claimed.

### FIELD

Embodiments of the present disclosure generally relate to the field of package assemblies, and in particular package assemblies having uniform thickness.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Continued growth in the number of mobile electronic devices such as smart phones and ultrabooks is a driving force for the development of packaging substrates with increased copper (Cu) density. This increase of density is a result, in part, of denser placements of chips and other elements on a substrate. As a result of this increased density, packages created from these substrates may have thickness differences across packages that may pose a variety of challenges for subsequent packaging processes. These challenges may include different via dimensions, bump formations, and the like in the packages.

Legacy buildup material lamination processes to create a package may include applying both vacuum presses as well as steel plate presses at elevated temperature. After the vacuum press is applied, the area with higher Cu density may have higher buildup layer thickness relative to the area with lower Cu density. Application of the subsequent steel plate press may be used to make the thickness uniform. However, the resin on the high Cu density area may not reliably flow to the low Cu density area because of large distance between those areas. This may result in thickness variations of the end packages.

### BRIEF DESCRIPTION OF THE DRAWINGS

FIGS. 1-4 illustrate example package assembly embodiments of stages of a slit coating process applied to a package assembly coated with a low viscosity resin to even the surface of the package and create uniform package thickness, in accordance with embodiments.

FIGS. 5-7 illustrate example package assembly embodiments of stages of an ultrasonic assisted hot press applied to a package assembly to even the surface of the package and to create a uniform thickness, in accordance with embodiments.

FIGS. 8-10 illustrate example package assembly embodiments of stages of a micro-scrubbing process applied to a package assembly to even the surface of the package and to create a uniform thickness, in accordance with embodiments.

FIG. 11 depicts an example flow diagram showing a process for manufacturing a package assembly such as package assembly shown in FIG. 4, according to various embodiments.

FIG. 12 depicts an example flow diagram showing a process for manufacturing a package assembly such as package assembly shown in FIGS. 7 and 10, according to various embodiments.

FIG. 13 schematically illustrates a computing device, in accordance with embodiments.

### DETAILED DESCRIPTION

Embodiments of the present disclosure generally relate to methods of assembling packages, which may include the use of a resin with exceptionally good flow that may be used in conjunction with a slit-coating process, an ultrasonic assisted hot press, and/or in micro-scrubbing assisted hot press to obtain a substantially uniform thickness in package assemblies.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

Various operations may be described as multiple discrete operations in turn, in a manner that is most helpful in understanding the claimed subject matter. However, the order of description should not be construed as to imply that these operations are necessarily order dependent. Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

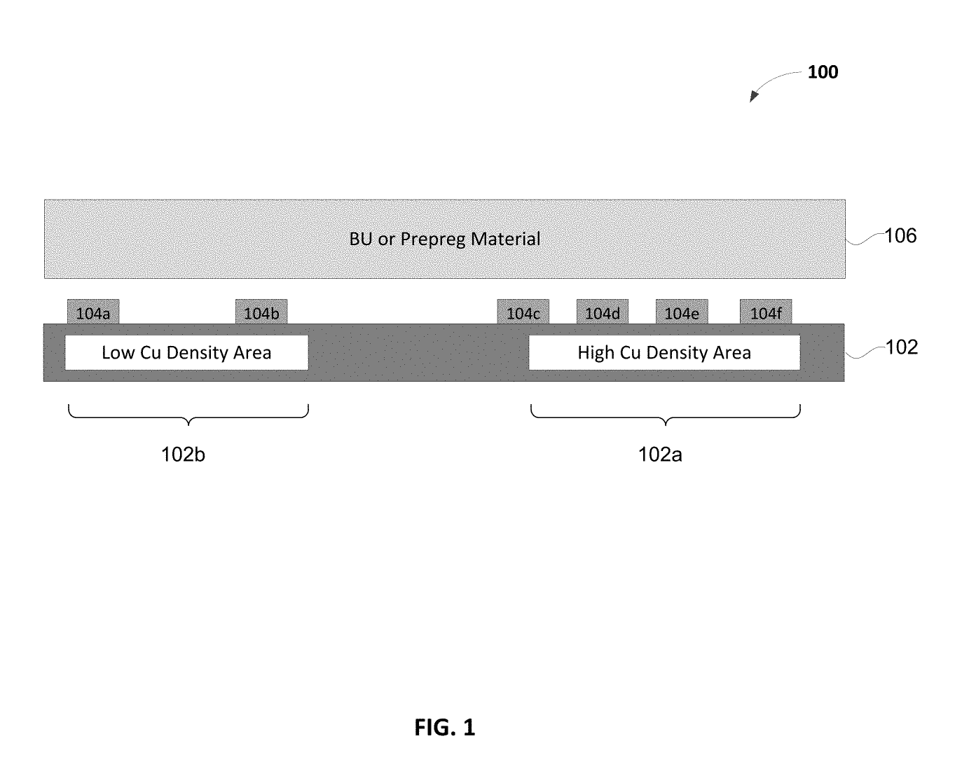

FIGS. 1-4 illustrate an example process of package assembly, showing various stages of a slit coating process applied to a package assembly, in accordance with some embodiments. As will be described below, the package may be coated with a low viscosity resin to even the surface of the package and create uniform package thickness.

FIG. 1 shows a package assembly embodiment 100 that includes a substrate 102 that may have various Cu elements 104a-104f attached on the substrate. In embodiments, the Cu element density across the packaging substrate 102 may vary widely because of, for example, high integration of various chips onto various locations of the substrate 102. In FIG. 1, a first group of Cu elements 104a-104b may be grouped in a low-density area on substrate 102, and a second group of Cu elements 104c-104f may be grouped in a high-density area on substrate 102.

A layer of buildup material 106 may be applied to the substrate 102. In embodiments, the buildup material 106 may be a legacy buildup film, or a pre-impregnated (pre-peg) material, for example composite fibers within a matrix material such as epoxy.

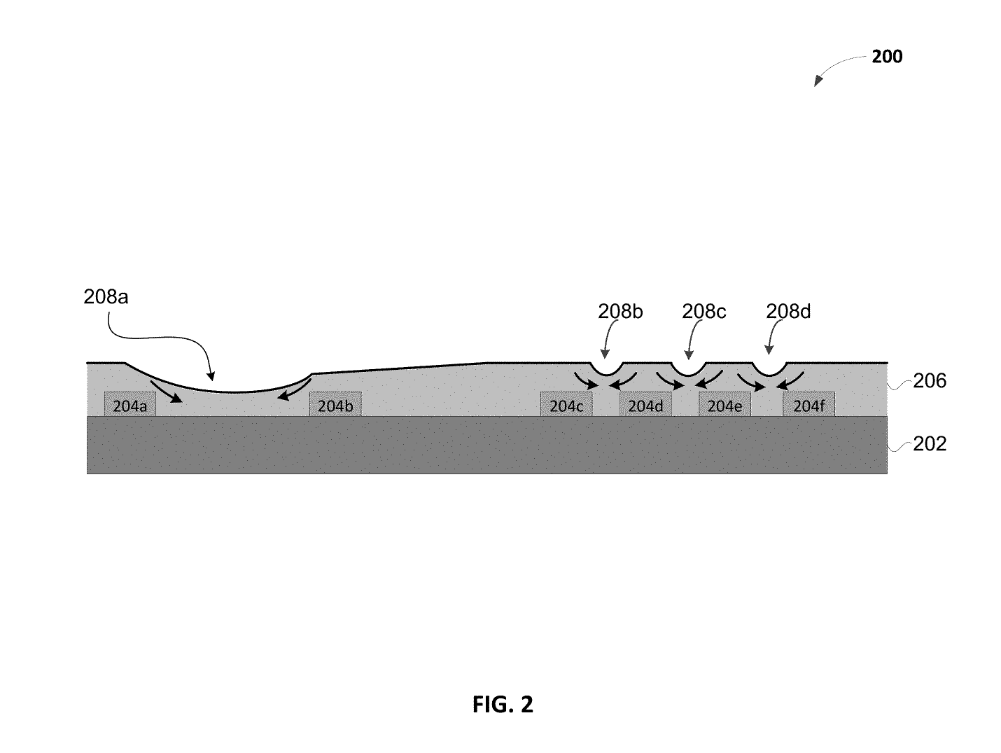

FIG. 2 shows a package assembly embodiment 200 where the buildup material 206, has been applied to the substrate 202 and surrounds Cu elements 204a-204f. The buildup material 206 may be similar to the buildup material 106 of FIG. 1; the substrate 202 may be similar to the substrate 102 of FIG. 1; and Cu elements 204a-204f, which may be similar to the Cu elements 104a-104f of FIG. 1.

In embodiments, a vacuum and/or conform press may be used to apply the buildup material 206. After the buildup material has been applied, undulations and/or recesses 208a-208d may develop due in part to the positioning of the Cu elements 204a-204f and the interaction of these elements that may advance or hinder the flow of the buildup material 206 as the is applied to the substrate 202.

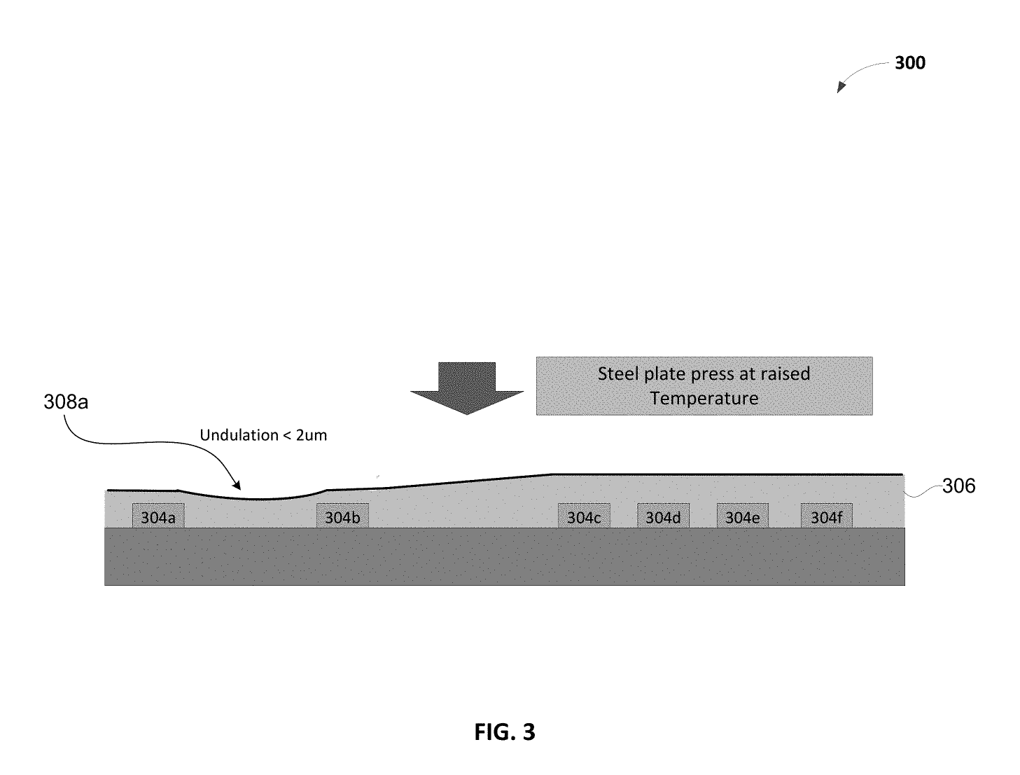

FIG. 3 shows a package assembly embodiment 300 where the buildup material 306, after it has been applied has undergone a steel plate press at a raised temperature. The buildup material may be similar to the buildup material 206 of FIG. 2. In embodiments, a steel plate (not shown) may be applied to the top of the buildup material 306, where the steel plate may be at a temperature of 50 Celsius (C) to 350 C, and the pressure applied may range from 0.001 Megapascal (MPa) to 10 MPa. The effect of the steel plate application process may be to partially level the top surface of the buildup layer 306 by compressing and causing the buildup layer 306 to flow and to fill in previous undulations and/or recesses. This may be accomplished, in part, by the buildup material 306 laterally shifting due to the application of the steel plate press.

However, after the steel plate application process, not all undulations and/or recesses may be filled. For example recess 308a, which may be similar to recess 208a in FIG. 2 may still exist. This may be due to the low viscosity of the buildup material 306.

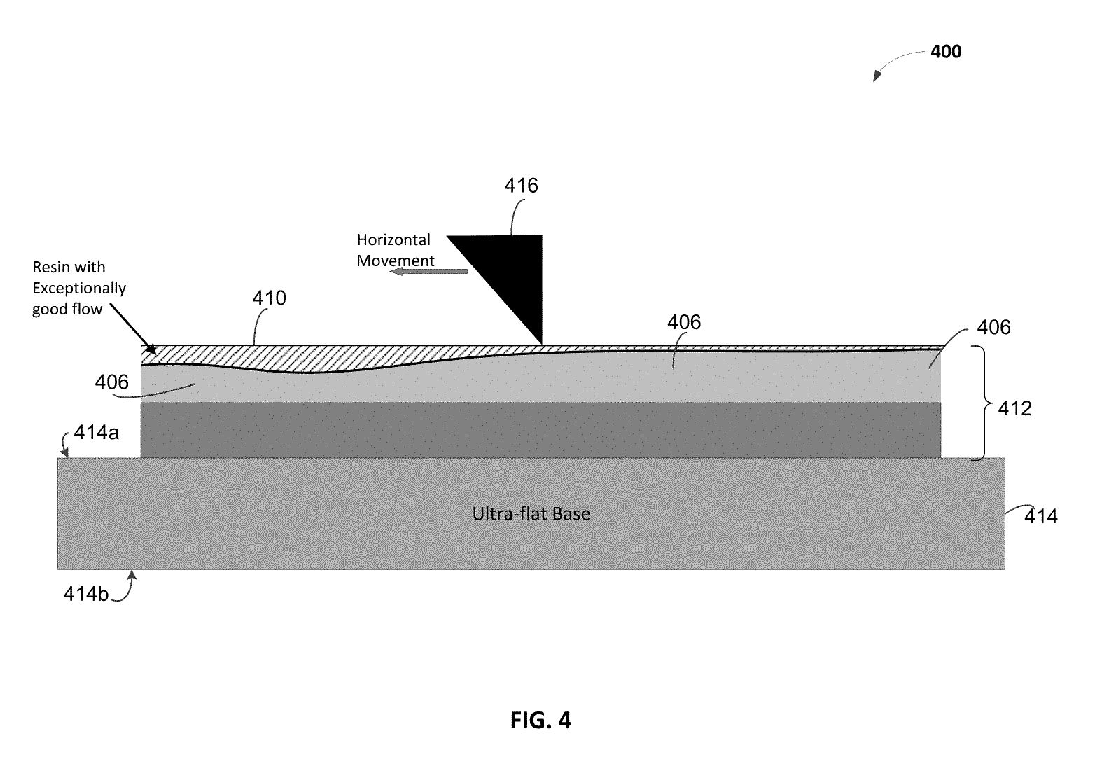

FIG. 4 is a package assembly embodiment 400 that shows an example of a slit coating process applied to a package assembly coated with a low viscosity resin to even the surface of the package. A layer of resin with low viscosity down to 10 Pascals (Pa) and exceptionally good flow 410 may be placed on top of the buildup material 406, which may be similar to the buildup material 306 of FIG. 3. In embodiments, the resin 410 may cover the entire top surface of the buildup material 406, or may cover only a portion of the top surface of the buildup material 406.

A slit coating process may then be applied to the package 412. In embodiments, the package 412 may be mounted on a base, which may be an ultraflat base 414. The ultraflat base may have less than a 1 micrometer (um) variation. In embodiments, small holes (not shown) through which air may pass from the bottom of the ultraflat base 414b to the top of the ultraflat base 414a may be used to secure the package 412 to the ultraflat base 414 by applying a vacuum (not shown) to the bottom of the ultraflat base 414.

A screed 416 may then be drawn across the top of the buildup layer 406 and/or the resin layer 410 to even out the resin layer 410 on the top of the package 412. In embodiments, the screed 416 may be one or more blades or a part of a blade. In embodiments, the blade 416 may be drawn across the package parallel to the ultraflat base 414 so that the top of the package 412 is substantially flat and parallel to the top of the ultraflat base 414a. This may result in a package 412 with a top and bottom that are parallel and are of uniform thickness.

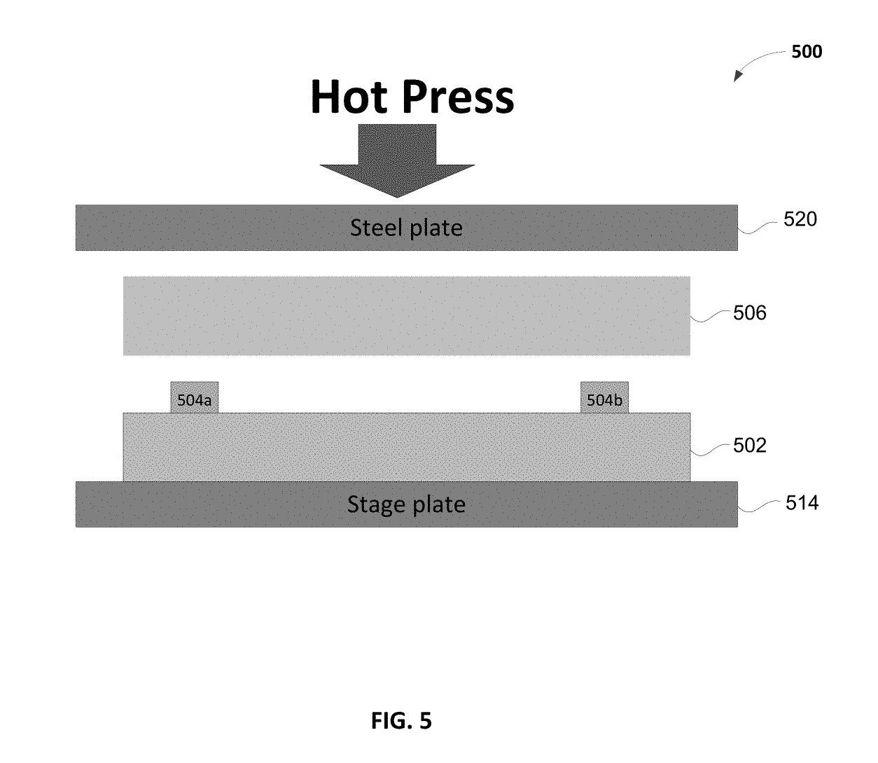

FIGS. 5-7 illustrate example package assembly stages of an ultrasonic assisted hot press applied to a package assembly, in accordance with embodiments. As will be described below, this may even the surface of the package and create a uniform package thickness.

FIG. 5 shows a package assembly embodiment 500 that includes a substrate 502 with Cu elements 504a, 504b applied to the substrate 502. The bottom of the substrate 502 may be attached to a stage plate 514. A build up material 506, which may be similar to buildup material 106 of FIG. 1, may be applied to the substrate 502 and attached Cu elements 504a, 504b using a steel plate 520 that may be heated and pressed on the buildup layer 506.

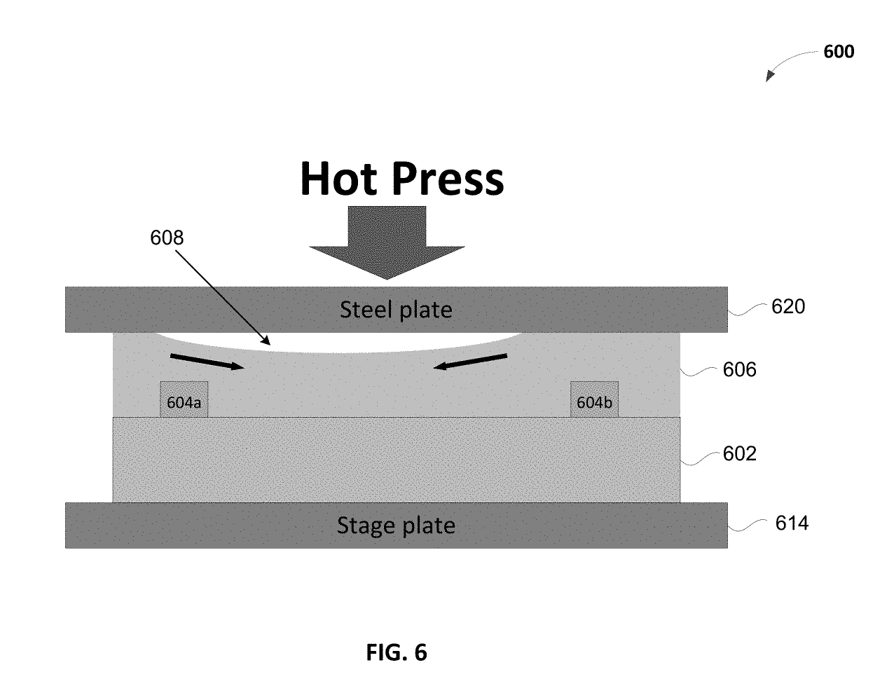

FIG. 6 shows a package assembly embodiment 600 after the steel plate 620, which may be similar to steel plate 520 of FIG. 5, has been pressed into buildup layer 606, which may be similar to buildup layer 506 of FIG. 5. In embodiments, the steel plate 620 is substantially parallel to the stage plate 614, which may be similar to the stage plate 514 of FIG. 5, on which the substrate 602, which may be similar to the substrate 502 of FIG. 5, may be attached. As a result of pressing the steel plate 620 into the buildup layer 606, an undulation 608 may appear between the bottom of the steel plate 620 and the top of the buildup layer 606. The undulation 608 may occur due to the restricted lateral flow of the buildup layer 606 during the hot press process caused by the density variations of the Cu elements 604a, 604b, which may be similar to the Cu elements 504a, 504b of FIG. 5. The hot press may be heated within a temperature range of 50 C to 350 C, and may be applied with a pressure of 0.001 MPa to 10 Pa.

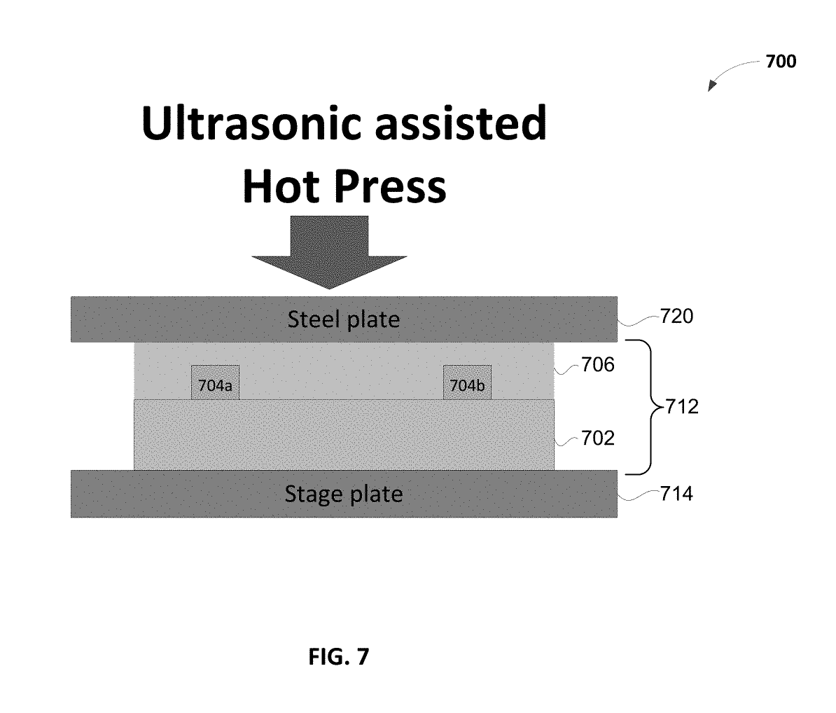

FIG. 7 shows a package assembly embodiment 700 after the steel plate 720 has been ultrasonically vibrated as the steel plate 720 was pressed against the buildup layer 706. The steel plate 720 may be similar to steel plate 620 of FIG. 6; and the buildup layer 706 may be similar to buildup layer 606 of FIG. 6.

In embodiments, the ultrasonic vibrations may be caused through high frequency pressure. The ultrasonic vibrations may occur at a frequency within a range of 20 kilohertz (kHz) to 400 kHz. The vibrations may cause the buildup layer 706 to reorient the molecular chains within the buildup layer 706 and to reduce surface undulation and roughness. As a result, the top of the buildup layer 706 may become substantially flat and parallel to the bottom of the substrate 702, which may be similar to the bottom of the substrate 602 of FIG. 6.

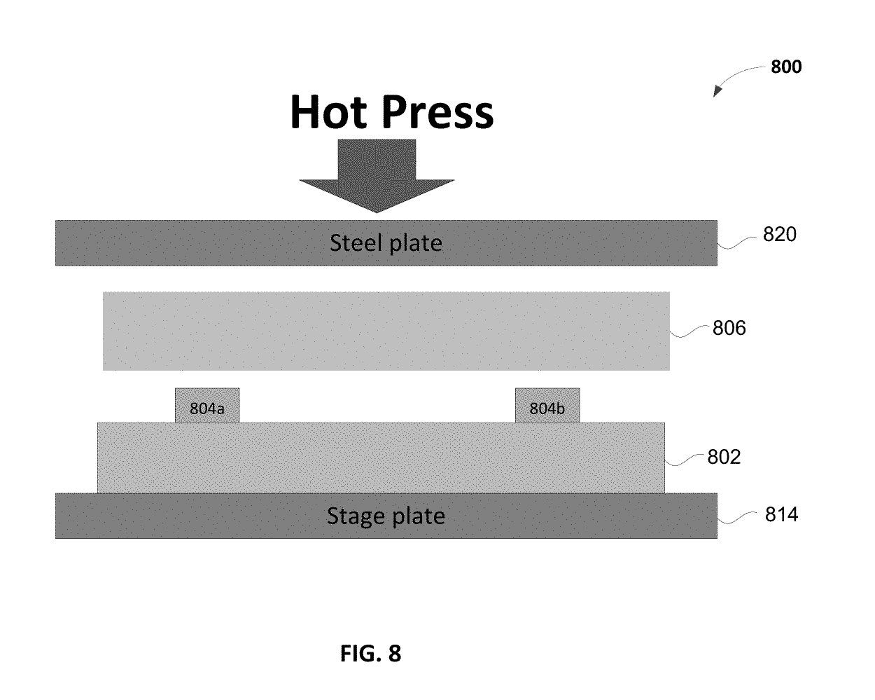

FIGS. 8-10 illustrate example package assembly stages of a micro-scrubbing process applied to a package assembly, in accordance with some embodiments. As will be described below, the process may even the surface of the package and to create a uniform package thickness, FIG. 8 shows a package assembly embodiment 800 that includes a substrate 802 with Cu elements 804a, 804b applied to the substrate 802. The substrate 802 may be attached to a stage plate 814. A build up material 806, which may be similar to buildup material 106 of FIG. 1, may be applied to the substrate 802 and attached Cu elements 804a, 804b using a steel plate 820 that may be heated and pressed on the buildup layer 806.

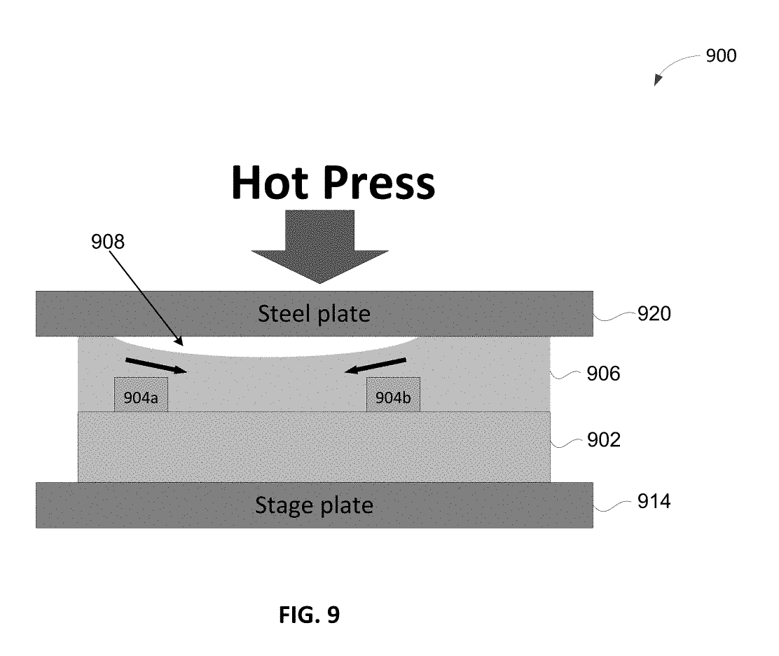

FIG. 9 shows a package assembly embodiment 900 after the steel plate 920, which may be similar to steel plate 820 of FIG. 8, has been pressed into buildup layer 906, which may be similar to buildup layer 806 of FIG. 8. In embodiments, the steel plate 920 is substantially parallel to the stage plate 914, which may be similar to the stage plate 814 of FIG. 8, on which the substrate 902, which may be similar to the substrate 802 of FIG. 8. As a result of pressing the steel plate 920 into the buildup layer 906, an undulation 908 may appear between the bottom of the steel plate 920 and the top of the buildup layer 906. The undulation 908 may occur due to the restricted lateral flow of the buildup layer 906 during the hot press process caused by the Cu elements 904a, 904b, which may be similar to the Cu elements 804a, 804b of FIG. 8. The hot press may be heated within a range of 50 C to 350 C. The pressure of the hot press may range from 0.001 MPa to 10 MPa.

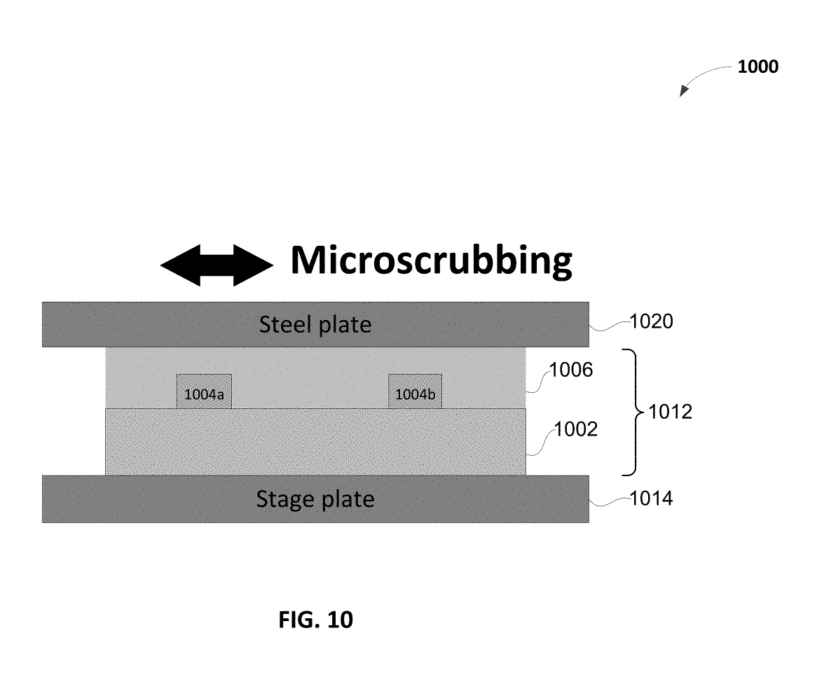

FIG. 10 shows a package assembly embodiment 1000 after the steel plate 1020, which may be similar to steel plate 920 of FIG. 9, has been moved in a scrubbing motion as the steel plate 1020 was pressed against the buildup layer 1006, which may be similar to buildup layer 906 of FIG. 9. In embodiments, the scrubbing motion may be caused through mechanical movement. The scrubbing motions may have an amplitude at or above a scrubbing threshold amplitude value. In embodiments, the threshold value may be down to a submicron level or a submicron scale. In embodiments, the threshold value may be at or near 0.1 micrometer (um). The scrubbing motions may cause the buildup layer 1006 to redistribute substantially evenly. In embodiments, the scrubbing motion may be referred to as a micro-scrubbing motion. As a result, the top of the buildup layer 1006 may become substantially flat and parallel to the bottom of the substrate 1002, which may be similar to the bottom of the substrate 902 of FIG. 9.

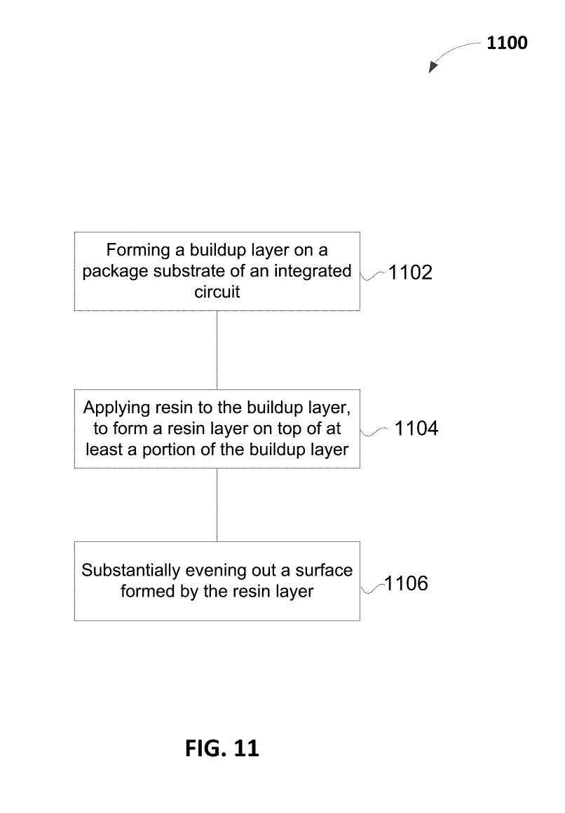

FIG. 11 depicts an example flow diagram showing a process 1100 for manufacturing a package assembly such as package assembly shown in FIG. 4, according to various embodiments.

At block 1102, the process may include forming a buildup layer on a package substrate of an integrated circuit. As described above, the buildup layer may be similar to buildup layer 106 of FIG. 1, and may be a buildup film or a pre-peg material.

At block 1104 the process may include applying resin to the buildup layer, to form a resin layer on top of at least a portion of the buildup layer. As described above, the resin layer may be similar to resin layer 410 of FIG. 4. In embodiments, the resin may have the characteristics of low viscosity down to 10 Pa and/or good flow. In embodiments, the resin may exhibit any ability to flow.

At block 1106, the process may include substantially evening out a surface formed by the resin layer. As described above, this may include applying a screed, such as screed 416 of FIG. 4, across the top surface of the resin layer to produce a package 412 with a uniform thickness and a smooth top surface.

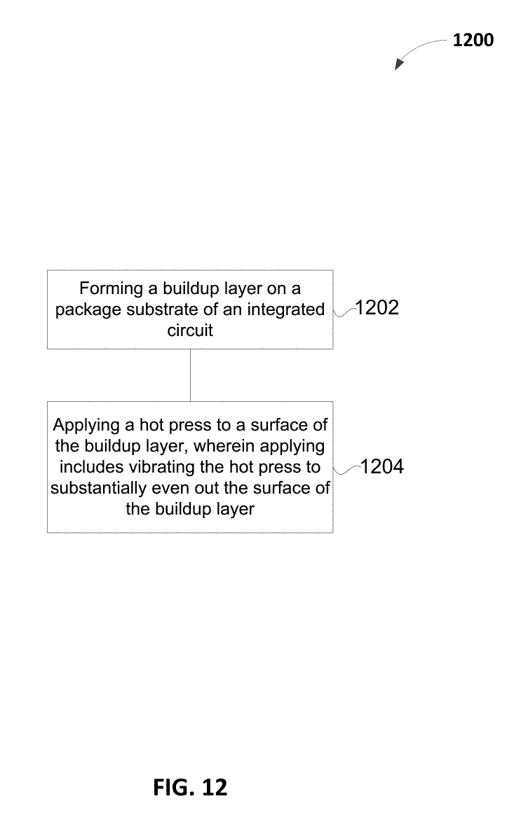

FIG. 12 depicts an example flow diagram showing a process 1200 for manufacturing a package assembly such as package assembly 712 shown in FIG. 7 and package assembly 1012 shown in FIG. 10, according to various embodiments.

At block 1202, the process may include forming a buildup layer on a package substrate of an integrated circuit. As described above, the buildup layer may be similar to buildup layer 606 of FIG. 6 or of buildup layer 906 of FIG. 9.

At block 1204, the process may include applying a hot press to a surface of the buildup layer, wherein applying includes vibrating the hot press to substantially even out the surface of the buildup layer. In embodiments vibrating the hot press may include vibrating the hot press ultrasonically, as described above with respect to embodiment 700 of FIG. 7. In embodiments, vibrating the hot press may include moving the hot press in a scrubbing motion, as described above with respect to embodiment 1000 of FIG. 10. In embodiments, vibrating the hot press, or vibrating a steel plate that is in contact with the hot press, may include vibrating using high-frequency pressure waves. In embodiments, the vibrating may include vibrating using Piezoelectric driven process to implement a Piezoelectric effect, and/or vibrating using Piezoelectricity.

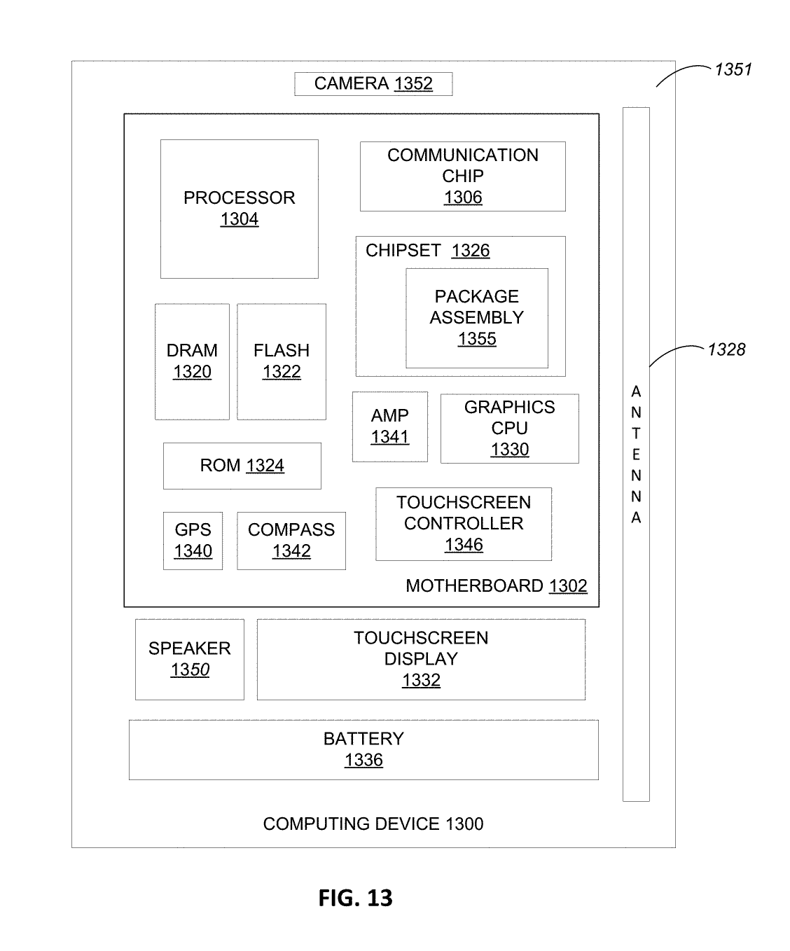

Embodiments of the present disclosure may be implemented into a system using any suitable hardware and/or software to configure as desired. FIG. 13 schematically illustrates a computing device 1300 in accordance with one embodiment. The computing device 300 may house a board such as motherboard 1302 (i.e. housing 1351). The motherboard 1302 may include a number of components, including but not limited to a processor 1304 and at least one communication chip 1306. The processor 1304 may be physically and electrically coupled to the motherboard 1302. In some implementations, the at least one communication chip 1306 may also be physically and electrically coupled to the motherboard 1302. In further implementations, the communication chip 1306 may be part of the processor 1304.

Depending on its applications, computing device 1300 may include other components that may or may not be physically and electrically coupled to the motherboard 1302. These other components may include, but are not limited to, volatile memory (e.g., DRAM) 1320, non-volatile memory (e.g., ROM) 1324, flash memory 1322, a graphics processor 1330, a digital signal processor (not shown), a crypto processor (not shown), a chipset 1326, an antenna 1328, a display (not shown), a touchscreen display 1332, a touchscreen controller 1346, a battery 1336, an audio codec (not shown), a video codec (not shown), a power amplifier 1341, a global positioning system (GPS) device 1340, a compass 1342, an accelerometer (not shown), a gyroscope (not shown), a speaker 1350, a camera 1352, and a mass storage device (such as hard disk drive, compact disk (CD), digital versatile disk (DVD), and so forth) (not shown). Further components, not shown in FIG. 13, may include a microphone, a filter, an oscillator, a pressure sensor, or an RFID chip. In embodiments, one or more of the package assembly components 1355 may be a package assembly such as package assembly 412 shown in FIG. 4, package assembly 712 shown in FIG. 7, or package assembly 1012 shown in FIG. 10.

The communication chip 1306 may enable wireless communications for the transfer of data to and from the computing device 1300. The term “wireless” and its derivatives may be used to describe circuits, devices, systems, processes, techniques, communications channels, etc., that may communicate data through the use of modulated electromagnetic radiation through a non-solid medium. The term does not imply that the associated devices do not contain any wires, although in some embodiments they might not. The communication chip 1306 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 1306 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1306 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1306 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1306 may operate in accordance with other wireless protocols in other embodiments.

The computing device 1300 may include a plurality of communication chips 1306. For instance, a first communication chip 1306 may be dedicated to shorter range wireless communications such as Wi-Fi and Bluetooth and a second communication chip 1306 may be dedicated to longer range wireless communications such as GPS, EDGE, GPRS, CDMA, WiMAX, LTE, Ev-DO, and others.

The processor 1304 of the computing device 1300 may include a die in a package assembly such as, for example, package assembly 412 provided as shown in FIG. 4, package assembly 712 provided as shown in FIG. 7, or package assembly 1012 provided as shown in FIG. 10. The term “processor” may refer to any device or portion of a device that processes electronic data from registers and/or memory to transform that electronic data into other electronic data that may be stored in registers and/or memory.

In various implementations, the computing device 1300 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1300 may be any other electronic device that processes data, for example an all-in-one device such as an all-in-one fax or printing device.

### Examples

Thus various example embodiments of the present disclosure have been described including, but are not limited to:

Example 1 may be a method for achieving substantially uniform package thickness, the method comprising: forming a buildup layer on a package substrate of an integrated circuit (IC); applying resin to the buildup layer, to form a resin layer on top of at least a portion of the buildup layer; and substantially evening out a surface formed by the resin layer.

Example 2 may include the method of example 1, further comprising depositing the package substrate on a base.

Example 3 may include the method of example 2, wherein the base comprises an ultra-flat base having a variation of less than 1 um.

Example 4 may include the method of example 2, wherein substantially evening out comprises applying a screed to move across the resin layer in a plane substantially parallel with the base.

Example 5 may include the method of example 4, wherein the screed is a blade component.

Example 6 may include the method of example 1, wherein substantially evening out the surface formed by the resin layer includes applying a slit coating process to at least the resin layer.

Example 7 may include the method of any one of examples 1-6, wherein the resin comprises a low viscosity material down to 10 Pascals (Pa).

Example 8 may include the method of any one of examples 1-6, wherein the buildup layer comprises a material pre-impregnated with resin.

Example 9 may include the method of any one of examples 1-6, wherein the package substrate includes one or more high copper density areas, and wherein the buildup layer encloses the one or more high copper density areas.

Example 10 may include the method of any one of examples 2-3, wherein the package substrate is secured to the base using a vacuum suction.

Example 11 may include the method of example 10, wherein the base further comprises a plurality of micro-tubes disposed inside the base through which a vacuum is to be drawn to secure the base to the package substrate.

Example 12 may be a method for achieving substantially uniform package thickness, the method comprising: forming a buildup layer on a package substrate of an integrated circuit (IC); applying a hot press to a surface of the buildup layer, wherein applying includes vibrating the hot press to substantially even out the surface of the buildup layer.

Example 13 may include the method of example 12, further comprising applying the hot press into the buildup layer and vibrating the hot press substantially simultaneously.

Example 14 may include the method of example 12, further comprising attaching the package substrate of an integrated circuit, IC, package assembly to a stage plate.

Example 15 may include the method of example 14, further comprising moving the hot press into the buildup layer in a direction perpendicular to the stage plate.

Example 16 may include the method of any one of examples 12-15, further comprising vibrating the hot press at or above a vibration threshold frequency.

Example 17 may include the method of any one of examples 12-15, wherein the vibration frequency is above 20 kHz.

Example 18 may include the method of any one of examples 12-15, further comprising vibrating the hot press in a scrubbing motion at a submicron level.

Example 19 may include the method of example 18, wherein the scrubbing motion is at or above a scrubbing threshold amplitude value.

Example 20 may include the method of example 19, wherein the scrubbing threshold amplitude value is 0.1 micrometer (um).

Example 21 may be a hot press for achieving substantially uniform package thickness, comprising: a steel plate; a heat source thermally coupled with the steel plate; and a press coupled with the steel plate, the press to: apply pressure to the steel plate in contact with a buildup layer of a package in a direction perpendicular to the plane of the steel plate; and cause the steel plate to vibrate to substantially even out a surface of the buildup layer.

Example 22 may include the hot press of example 21, wherein the press is further to apply pressure to the steel plate and to cause the steel plate to vibrate substantially simultaneously.

Example 23 may include the hot press of any examples 21-22, wherein the press is to cause the steel plate to vibrate at or above a vibration threshold frequency.

Example 24 may include the hot press of example 23, wherein the vibration threshold frequency is 20 MHz.

Example 25 may include the hot press of any examples 21-22, wherein the press is to cause the steel plate to vibrate in a scrubbing motion.

Example 26 may include the hot press of example 25, wherein vibrating the steel plate in a scrubbing motion includes vibrating the steel plate using high frequency pressure waves or piezoelectricity.

Example 27 may include the hot press of example 25, wherein the scrubbing motion is at or above a scrubbing threshold amplitude value.

Example 28 may include the hot press of example 25, wherein the scrubbing threshold amplitude value is 0.1 um.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

1. A method for achieving substantially uniform package thickness, the method comprising:
forming a buildup layer on a package substrate of an integrated circuit, IC;
applying resin to the buildup layer, to form a resin layer on top of at least a portion of the buildup layer; and
substantially evening out a surface formed by the resin layer.

2. The method of claim 1, further comprising depositing the package substrate on a base.

3. The method of claim 2, wherein the base comprises an ultra-flat base having a variation of less than 1 um.

4. The method of claim 2, wherein substantially evening out comprises applying a screed to move across the resin layer in a plane substantially parallel with the base.

5. The method of claim 2, wherein the package substrate is secured to the base using a vacuum suction.

6. The method of claim 1, wherein substantially evening out the surface formed by the resin layer includes applying a slit coating process to at least the resin layer.

7. The method of claim 1, wherein the resin comprises a material with a viscosity of at least 10 Pascals (Pa).

8. The method of claim 1, wherein the package substrate includes one or more high copper density areas, and wherein the buildup layer encloses the one or more high copper density areas.

9. A method for achieving substantially uniform package thickness, the method comprising:
forming a buildup layer on a package substrate of an integrated circuit, IC;
applying a hot press to a surface of the buildup layer, wherein applying includes
vibrating the hot press to substantially even out the surface of the buildup layer.

10. The method of claim 9, further comprising applying the hot press into the buildup layer and vibrating the hot press substantially simultaneously.

11. The method of claim 9, further comprising attaching the package substrate of an integrated circuit, IC, package assembly to a stage plate.

12. The method of claim 11, further comprising moving the hot press into the buildup layer in a direction perpendicular to the stage plate.

13. The method of claim 9, further comprising vibrating the hot press at or above a vibration threshold frequency.

14. The method of claim 9, wherein the vibration frequency is above 20 kHz.

15. (canceled)

16. A hot press for achieving substantially uniform package thickness, comprising:
a steel plate;
a heat source thermally coupled with the steel plate; and
a press coupled with the steel plate, the press to:
apply pressure to the steel plate in contact with a buildup layer of a package in a direction perpendicular to the plane of the steel plate; and
cause the steel plate to vibrate to substantially even out a surface of the buildup layer.

17. The hot press of claim 16, wherein the press is further to apply pressure to the steel plate and to cause the steel plate to vibrate substantially simultaneously.

18. The hot press of claim 16, wherein the press is to cause the steel plate to vibrate at or above a vibration threshold frequency.

19. The hot press of claim 18, wherein the vibration threshold frequency is 20 MHz.

20. The hot press of claim 16, wherein the press is to cause the steel plate to vibrate in a scrubbing motion.
